(19) United States
(12) Patent Application Publication
(10) Pub. No.: US 2023/0057103 A1
(43) Pub. Date: Feb. 23, 2023

(54) REMOTE DEPLOYABLE, POWERED, WIRELESS EDGE-DEVICE

(71) Applicant: FORD GLOBAL TECHNOLOGIES, LLC, Dearborn, MI (US)

(72) Inventors: Punarjay Chakravarty, Campbell, CA (US); Armin Parchami, Ann Arbor, MI (US); Sagar Manglani, Cupertino, CA (US); Gaurav Pandey, College Station, TX (US)

(21) Appl. No.: 17/405,361

(22) Filed: Aug. 18, 2021

(51) Int. Cl. H04N 5/225; H04N 5/247

(52) U.S. Cl. CPC H04N 5/2252; H04N 5/247; H04N 5/22521

(57) ABSTRACT

A sensor device includes a multi-part retainable shell, including an exterior outward facing wall and an interior wall shaped in accordance with a mounting element about which the shell is to be secured. The apparatus includes one or more processors provided to the hollow interior and one or more heat sinks provided on the outer wall, capable of carrying heat away from the hollow interior. The apparatus also includes a plurality of sensors provided to the outer wall to create a sensor field-of-view in a direction facing outward from the outer wall, the sensors each in communication with a processor. The parts of the shell are securable to each other in a manner that causes friction inducing material provided to the inner wall to substantially contact a mounting pole with sufficient force to prevent vertical slippage of the apparatus when the parts are secured to each other.

### TECHNICAL FIELD

The illustrative embodiments generally relate to a remotely deployable, powered, wireless edge device.

### BACKGROUND

Smart cities, and eventually a smart world, will require significant deployed processing and information sharing capability. This may literally require deploying dozens of devices in a fixed proximity, and perhaps tens of millions of devices world wide. Accordingly, the cost effectiveness of such devices is paramount, as is ease of deployment, ease of replacement, etc.

Powering such devices will also create a burden in conventional infrastructure, as complicated powering solutions could be needed to deploy standard electrical connections to each device. Further, those devices would then potentially suffer from power outages, which could render entities, such as autonomous vehicles, which may rely on such devices to function, crippled for a period of time. Redundancies, backup devices, etc., all add to the complexities and costs of overall establishment of such a system.

In furtherance of the goal of a smart world, there is a focus on technologies that are useful, cost-effective and which address one or more of the above concerns. Development and deployment of these devices will be a crucial step in achieving a fully connected environment.

### SUMMARY

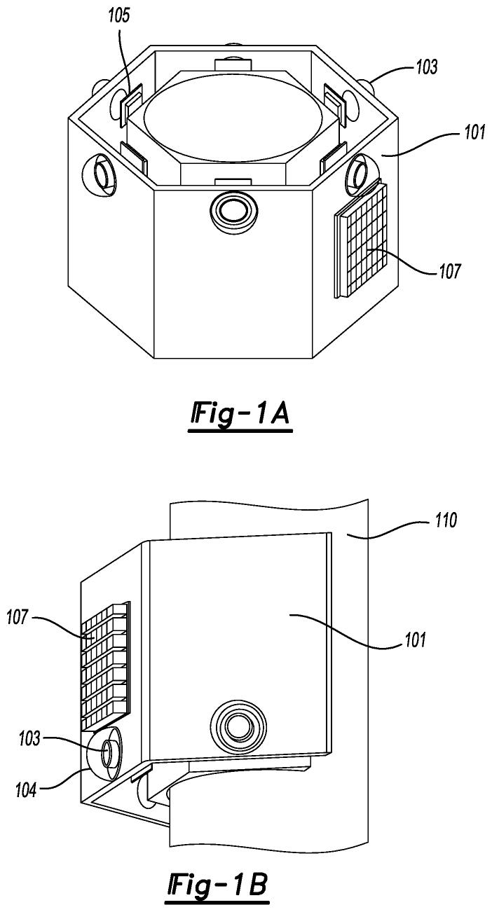

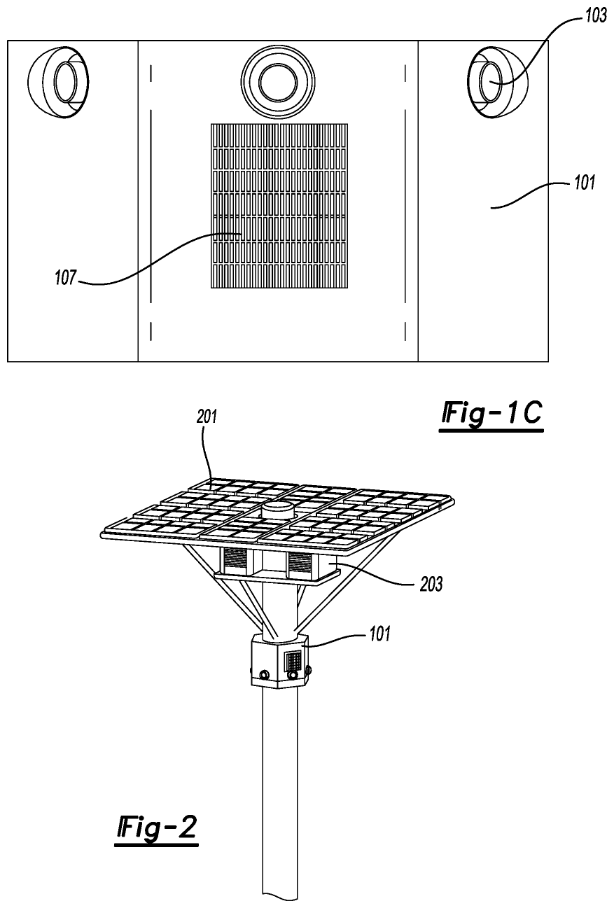

FIG. 1A shows an illustrative example of a sensor device;

FIG. 1B shows an illustrative example of one half of a dual-part sensor device;

FIG. 1C shows an illustrative example of a front view of a facet of a multi-faceted sensor device;

FIG. 2 shows an illustrative example of a deployed sensor device with illustrative power solution;

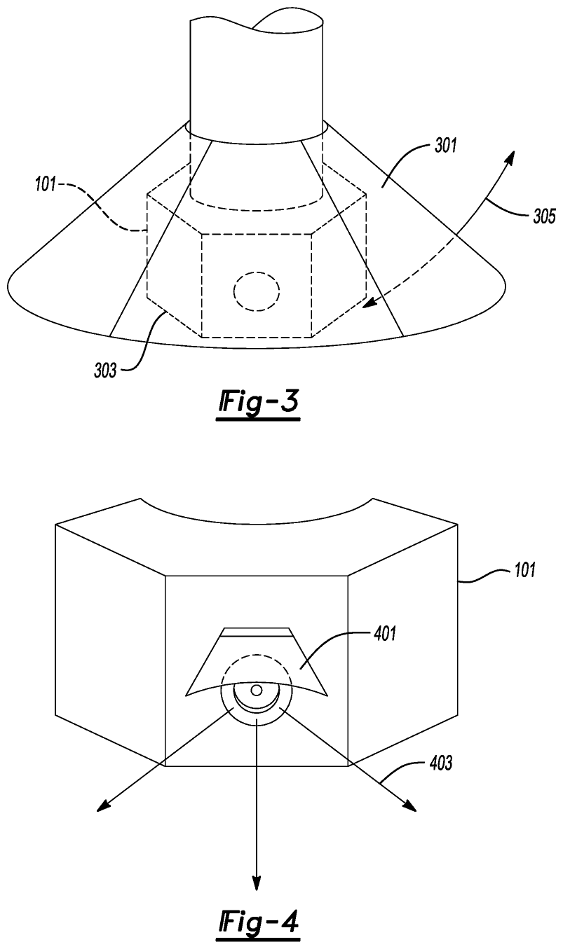

FIG. 3 shows an illustrative example of cross-linked element shield; and

FIG. 4 shows an illustrative example of a localized element shield.

### BRIEF DESCRIPTION OF THE DRAWINGS

In a first illustrative embodiment, an apparatus includes a multi-part retainable shell, including an exterior outward facing wall and an interior wall, with a hollow interior between the outer and inner walls, sealed against exterior intrusion. The apparatus further includes one or more processors provided to the hollow interior and one or more heat sinks provided on the outer wall, capable of carrying heat away from the hollow interior. The apparatus also includes a plurality of sensors, at least one provided to at least two of the parts of the multi-part shell, provided to the outer wall to create a sensor field-of-view in a direction facing outward from the outer wall, the sensors each in communication with at least one of the one or more processors, wherein the parts of the multi-part shell are securable to each other in a manner that causes friction inducing material provided to the inner wall to substantially contact a mounting pole with sufficient force to prevent vertical slippage of the apparatus when the parts are secured to each other.

In a second illustrative embodiment, an apparatus includes a multi-part retainable shell, including an exterior outward facing wall and an interior wall, with a hollow interior between the outer and inner walls, sealed against exterior intrusion. The apparatus also includes one or more processors provided to the hollow interior and one or more heat sinks provided on the outer wall, capable of carrying heat away from the hollow interior. Further, the apparatus includes a plurality of sensors, at least one provided to at least two of the parts of the multi-part shell, provided to the outer wall to create a sensor field-of-view in a direction facing outward from the outer wall, the sensors each in communication with at least one of the one or more processors. The apparatus additionally includes an adjustable shield adjustable along at least one axis providing shielding at least above at least one of the sensors, and retainable in an adjusted position to resist movement from exterior environmental forces, wherein the parts of the multi-part shell are securable to each other in a manner that causes friction inducing material provided to the inner wall to substantially contact a mounting pole with sufficient force to prevent vertical slippage of the apparatus when the parts are secured to each other.

In a third illustrative embodiment, an apparatus includes a dual-part retainable shell, each part including a faceted exterior outward facing wall and an interior wall, with a hollow interior between the outer and inner walls, sealed against exterior intrusion. The apparatus also includes one or more processors provided to the hollow interior of each of the dual parts. Further the apparatus includes one or more heat sinks provided on the outer wall of each of the dual parts, capable of carrying heat away from the hollow interior and a plurality of sensors, at least one provided to each part of the shell, provided to a facet of the outer wall to create a sensor field-of-view in a direction facing outward from the outer wall, the sensors each in communication with at least one of the one or more processors of a respective part of the shell to which the sensor is provided and each being rotatably adjustable along at least two axes. The parts of the dual part shell are oppositionally securable to each other in a manner that causes friction inducing material provided to the inner wall to substantially contact a mounting pole with sufficient force to prevent vertical slippage of the apparatus when the parts are secured to each other.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

In addition to having exemplary processes executed by a vehicle computing system located in a vehicle, in certain embodiments, the exemplary processes may be executed by a computing system in communication with a vehicle computing system. Such a system may include, but is not limited to, a wireless device (e.g., and without limitation, a mobile phone) or a remote computing system (e.g., and without limitation, a server) connected through the wireless device. Collectively, such systems may be referred to as vehicle associated computing systems (VACS). In certain embodiments, particular components of the VACS may perform particular portions of a process depending on the particular implementation of the system. By way of example and not limitation, if a process has a step of sending or receiving information with a paired wireless device, then it is likely that the wireless device is not performing that portion of the process, since the wireless device would not “send and receive” information with itself. One of ordinary skill in the art will understand when it is inappropriate to apply a particular computing system to a given solution.

Execution of processes may be facilitated through use of one or more processors working alone or in conjunction with each other and executing instructions stored on various non-transitory storage media, such as, but not limited to, flash memory, programmable memory, hard disk drives, etc. Communication between systems and processes may include use of, for example, Bluetooth, Wi-Fi, cellular communication and other suitable wireless and wired communication.

In each of the illustrative embodiments discussed herein, an exemplary, non-limiting example of a process performable by a computing system is shown. With respect to each process, it is possible for the computing system executing the process to become, for the limited purpose of executing the process, configured as a special purpose processor to perform the process. All processes need not be performed in their entirety, and are understood to be examples of types of processes that may be performed to achieve elements of the invention. Additional steps may be added or removed from the exemplary processes as desired.

With respect to the illustrative embodiments described in the figures showing illustrative process flows, it is noted that a general purpose processor may be temporarily enabled as a special purpose processor for the purpose of executing some or all of the exemplary methods shown by these figures. When executing code providing instructions to perform some or all steps of the method, the processor may be temporarily repurposed as a special purpose processor, until such time as the method is completed. In another example, to the extent appropriate, firmware acting in accordance with a preconfigured processor may cause the processor to act as a special purpose processor provided for the purpose of performing the method or some reasonable variation thereof.

In one model of a smart environment, infrastructure (IX) devices may be deployed about an environment (such as an intersection). Some may be sensing devices, some may be computing devices, some may be data-relay devices, and some devices may serve more than one function. Sensors, such as, but not limited to, cameras, may need a full view of any areas where a vehicle may encounter an object. Pathing predictions, such as predicting whether a pedestrian will enter an intersection, may require an even more robust view, so in an optimal scenario the sensors will have full coverage of an area of interest. Even if this in not perfectly achievable, multiple views and angles of countless positions may be needed to ensure that any temporary blockages (a high truck, an ill-perched bird, etc.) do not wreak havoc on the ability of vehicles to perceive an environment based on information conveyed from the sensors.

Multiple IX devices may be connected in an environment, through short range low power wireless communication, and localized processing may be used to combine sensed information into a comprehensive data-flow to be sent to requesting entities, such as vehicles. This data effectively allows vehicles to “see around corners” and see areas that typically could not be reached by vehicle sensors.

The illustrative embodiments propose an aspect of the sensor-suite, which includes a small, low power, low-cost panoramic sensing and computing device that can be weather sealed and securely pole-mounted, in one example.

In one version of the illustrative embodiments, the device can be assembled in two halves, which oppositionally secure to a pole or central mounting feature, encompassing the feature and using a friction mount achieved by securing the two halves to each other.

In one example, the device may be hexagonal with six total glass portholes and six total camera sensors, one of each provided to each face of the object. While the object could have more or fewer sides, sensors and sensors per-side, the device must also be able to power the sensors. More sensors might be feasible, but might also require selective powering or other alternating engagement. This could increase the cost of the device as well, so the choice of sensors and powering strategies may partially be a function of cost, battery life, usage expectations, etc.

The interior of the device can be provided with an inner wall configured to mounting-pole shape, such as circular, rectangular, square, etc. By keeping the sensor choices in line with battery power and expected usage, configuration can be optimized based on deployment strategy. The device may also include one or more batteries that can be powered by solar power, for example, wherein a solar array above the device may provide both a power source and a shield from the elements. Even if the device is sealed against the elements, heat sinks can carry heat away from the device to preserve device-life.

FIG. 1A shows an illustrative example of a sensor device. In this example, the device 101 is a dual-part device having oppositionally securable halves and six facets. It is appreciated that multiple securable configurations can be used (hinged, multi-part, etc.) and that the general principle of the illustrative example is to provide a device that is reasonably securable to semi-standardized pole mounts. In examples where the poles may be differently shaped and or of different circumferences, or even oddly shaped or deformed because of elemental damage and time, adjustable inner wall retention elements could be included (feet, a moveable wall, etc) so that a secure friction mount could be achieved relative to each facet or most facets, holding the device in place by the oppositional forces provided by the retention elements or friction elements being held against the pole when the device is unified and secured. Other mounting solutions could also be provided and the broader concept is to provide a device that is suitable for mounting in a broad range of commonly encountered deployment scenarios, without necessarily having to customize the inner wall of the device for each deployment during manufacture. Multiple inner-wall versions can also be used, based on types of planned deployment.

Retention plates or feet could be securely affixed to the inner wall (to preserve the sealed integrity and screw adjustable or otherwise adjustable relative to a position between the inner wall and the pole. This would still allow for rapid, on-site-configurable deployment, wherein an installer may simply have to adjust the retention elements slightly to accommodate a particular deployment (e.g., an irregularly shaped pole or a dented or twisted pole).

The facets of the device, in this example, include sensors 103, (in this example, cameras), with lens covers where needed. Each facet covers a different field of view, although there may be some overlap at the edges of fields of view to account for potential obstruction of a given sensor 103. The cameras are supported by and connected to onboard processing, which in this example is one or more onboard microprocessors 105. The microprocessors are housed within the casing of the device (one per side in this example) and include heat sinks 107 secured to the exterior of the device, which in this instance can carry heat away from the device without necessarily requiring piercing of the sealed shell. If the shell itself is heat conductive, additional heat sinks can be deployed to further dissipate heat, while may be required in certain environments. In other instances, the shell may be heat-resistant and only a portion of the shell to which the heat-sink is provided may be conductive of heat, in order to carry heat to the sink while preventing overheating from exterior sources (e.g., a hot day in Arizona). General concepts about heat dissipation and retention apply to the design of the shell and can be used as appropriate for solutions based on intended deployment and overall heat generation of a given solution (e.g., more processing intensive devices and or environmental effects may require different sink solutions for different devices).

The device may powered by batteries, with the batteries themselves being charged by solar power. If the batteries produce significant heat in a solution, they can be isolated from the rest of the shell by insulated material, and their own heat can be further dissipated via additional heat sinks if needed. In those solutions, the batteries may be provided to the shell interior, and wired to the elements they power, but otherwise isolated by insulated material to force the battery heat away from the interior and into the sinks provided for the batteries. In other examples, the batteries can be connected to the shell via power hookups that preserve the sealed shell interior and which themselves may be reasonably sealed (e.g., a screw-cover connector), but which also keeps the batteries separate from the shell and allows them to dissipate their own heat, as well as be replaced without having to replace the shell itself.

The device may further be provided with one or more communication elements, such as, but not limited to, a transceiver or transmitter, which can include BLUETOOTH, DSRC, UWB, Cellular, Wi-Fi, etc. Power consideration and the ability to run the sensors as frequently as desired, up to a 24 hour 7 day a week cycle, is a consideration in component choice and can be affected by transmitter/transceiver choice as well.

In one example, 2 computing devices consume 15 W of power/hr each, 6 cameras (in a hexagonal configuration) consume 1.25 W/hr each, and a wireless connection for each compute device consumes 5 W/hr. This adds up to 47.5 W per hour. Adjustment may be made in some instances depending on frequency of communication and whether elements can be placed in low-power modes at times when they may be less necessary. Nonetheless, the above provides a 1140 Whr requirement for running the device 24 hours a day.

In a city that has an average of, for example, 5 hours of sunlight in January (or whatever month where sunlight is the lowest average), solar arrays capable of regenerating 228 W/hr would be needed. If there was an efficiency loss of 50%, 456 W/hr of generation might be needed. In another city, with only 2.75 hours of sunlight, 830 W/hr generation would be required.

A further consideration is battery number and size, since sunlight may not be consistently available on all days. In the sunnier city, the month of lowest sunlight may have 17 days of light (e.g., January), requiring 31/17*total power (1140) hours of storage. This would reasonably maintain power, however additional accommodation may be needed for the likelihood that there are a certain number of sunless days in a row. Based on locality, it may be known that, for example, there are frequently 3 sunless days in a row, if the expected number of sunless days exceeds the number of days in the month (31) divided by the number of days of sunlight (17), then batteries that accommodate the expected number of sunless days (3) times the total power usage (1140 W) may be required if there is an expectation of 24/7 operation.

If the onboard communication device is a transceiver, it may be possible to periodically upload weather data (e.g., at least expectations of sunniness) so that the onboard computer(s) can potentially take strategic shutdown actions if power needs to be preserved. E.g., if there is an expected week without sunlight, the cameras or sensors may be more useful from the hours of 5 AM to midnight, and so the system can go into low power mode or standby mode for a number of less-important hours each day to preserve power until sunlight returns. Additionally or alternatively, the sensors may be limited in usage, wherein fewer than all the sensors may be used.

Even in the absence of a transceiver, the computing devices may have an onboard design to limit power usage if the battery supply falls below a certain threshold, so that attempts can be made to accommodate unexpected lack of sunlight and keep the cameras functional for the longest period of time during peak hours.

If the device(s) are used to support autonomous vehicle driving or other functions, then it may be necessary to have them running 24/7, and so sufficient battery supply may be needed to accommodate all but the most unlikely of scenarios. This, of course, would come at an increased cost. Also, in order to keep power in the batteries, sufficient overage of power may need to be accommodated such that the batteries are kept at a desired level even if maximum usage occurs. Otherwise, in the absence of peak generation, the batteries may not be as full as desired, and the operational duration during such times may be diminished. The solar array should often be generating more power than is consumed directly during sunlight hours, but may still be chosen to generate sufficient power during such times to ensure that the maximum battery duration is preserved if that particular day happens to be the only day in a long stretch of otherwise sunless days.

Again, the criticality of the device may dictate constraints, in systems where the device is providing useful, but not necessary (e.g., necessary for AVs to operate) information, there may be some acceptable down-time in exchange for significantly reduced cost, in the event of unexpected prolonged lack of sunlight. In the most crucial scenarios, it may be desirable to provide an array capable of providing full battery charge, from 0 charge, during only several hours of sunlight, in addition to accommodating any usage during that time period. The downside of such a scenario is that much generation may be wasted during other times of the year, and so the duration of such weather events and the effect that those events may have may be considered relative to the cost increases of adding all the additional generation and battery storage capacity.

FIG. 1B shows an illustrative example of one half of a dual-part sensor device, secured to a mounting pole 110. This heat sink 107 provided to the processor 105 (not shown) is seen in profile, and the sensors 103 are covered by lenses 104, which may be treated in a manner to best avoid accumulation of grit, dust and other precipitates.

FIG. 1C shows an illustrative example of a front view of a facet of a multi-faceted sensor device 101, showing the varied fields of view achieved by the three sensors 103 and the heat sink being deployed in relative position to the interior processor 105 (not shown). Again, if the shell interior is hollow, allowing heat to move within the shell interior, additional heat sinks may be provided.

FIG. 2 shows an illustrative example of a deployed sensor device with illustrative power solution, which in this instance is a solar array 201 connected to batteries 203. The device 101 itself is mounted beneath the array 201, providing some general cover from the environment. The batteries 203 sit separate from the device, allowing for replacement and heat dissipation without affecting the device 101. Power hookups that are provided to the shell can allow for sealed connections that are weather-proof and themselves may be shielded at the connection points, such as through weather-securable fasteners that are generally weatherproof when fully connected.

FIG. 3 shows an illustrative example of cross-linked element shield 301. This is a non-limiting example of a whole or partial device adjustable shield that can provide overhead and partial side coverage. This shield can be raised in direction 305, fanning out the linked leaves 303. Since the sensors still need a field-of-view, coverage to the upper portions and to the sides above a maximum desired viewing angle may be provided. Since the cameras may be on-site adjustable (e.g., rotatable about a 3 degree axis), the shield itself may be downwardly adjustable based on maximum desired viewing angles along each axis, so that even if the shield is seen in sensor data, it is blocking areas where coverage is not needed, (e.g., upwards).

Thus, if a camera is aimed more downwards, the shield could be lowered more, providing greater protection against elements and precipitates, and if the camera is aimed more outwards, the shield could be raised so as not to obstruct the view.

While the shield 301 may be adjustable along one or more axis, and various embodiments, could be used, in this example the leaves 303 of the shield are interlinked, so that they move in concert, creating an adjustable cone above the device 101. In other examples, the leaves may have no linkage, and each may be adjustable independently, which may be more useful if the cameras have different horizontal aimings. A lower-side shield could be comparably used if up-spray was a concern, similarly adjustable so as not to affect a field of view. In other examples, a conical or semi-conical shield defining the maximum width of a field of view could be affixed to an adjustable lens cover, so that rotation of the cover rotated the lens and shield in concert. Such a shield may make it more difficult to clean a lens cover, however, depending on how deep the cone was.

Such shielding may be retainable in an adjusted-position via screws or other affixation, preventing incidental movement from wind and elements once set to a desired position relative to the field of view.

FIG. 4 shows an illustrative example of a localized element shield 401. This is an adjustable element provided directly to the lens 104 or above or to the side of the lens. In a simple form, it is a trapezoid or curved trapezoid, although that shape is merely illustrative. Again, the shield may be adjusted based on an intended field of view 403, so that the outer edges of the shield do not obstruct the view. The lower the shield, the generally better the protection, but also the greater the restriction on the field of view, and this will be contemplated when choosing a shield shape and deployment strategy for a given deployed solution. The shielding can be integrated with or separate from the device 101, and be retainable in similar manners. Other shielding may be height adjustable (relative to device mount) and rigid in configuration, so that it is merely raised or lowered relative to the device in terms of mounting, and then affixed in place. Conical or semi-spherical shielding can be deployed in this manner and mounted so that the lower edge does not obstruct the field of view. Localized environmental conditions may dictate the choice of shielding as well, based on whether weather and debris tends to come at the lens cover from above, the sides or below.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

1. An apparatus comprising:
two half-shells, each having an outer wall and an inner wall and defining a hollow interior between the outer and inner walls;
one or more processors provided to the hollow interior;
one or more heat sinks provided on the outer wall, capable of carrying heat away from the hollow interior; and
a plurality of sensors, at least one provided to each of the half-shell, the sensors each in communication with at least one of the one or more processors,
wherein the half-shells are secured to one another surrounding a mounting pole and wherein an exterior surface of the inner wall frictionally engages the mounting pole.

2. (canceled)

3. The apparatus of claim 1, wherein the exterior surface of the inner wall is cylindrical.

4. (canceled)

5. The apparatus of claim 1, wherein the inner wall includes friction inducing material provided to an exterior surface thereof.

6. (canceled)

7. The apparatus of claim 1, wherein the sensors include cameras.

8. (canceled)

9. The apparatus of claim 1, wherein the outer wall is faceted, with at least one of the sensors provided to each facet.

10. The apparatus of claim 1, including an exterior power hookup that provides power to the one or more processors and at least one of the sensors.

11. The apparatus of claim 10, wherein the apparatus further comprises at least one solar power source connectable to the exterior power hookup.

12. An apparatus comprising:
two half-shells, each half-shell comprising
an outer wall;
an inner wall;
a processor; and
a plurality of sensors each in communication with the processor; wherein
the two half-shells are securable to each other such that they surround a mounting pole and provide the sensors with a panoramic field-of-view unencumbered by the mounting pole.

13. The apparatus of claim 12, wherein each half-shell further comprises a heat sinks secured to a heat-conductive material incorporated in the outer wall.

14. The apparatus of claim 12, wherein the inner wall is cylindrical.

15. (canceled)

16. The apparatus of claim 12, wherein the inner wall includes friction inducing material provided to a surface thereof that will face the mounting pole.

17. (canceled)

18. The apparatus of claim 12, wherein the sensors include cameras.

19-20. (canceled)

21. The apparatus of claim 1 wherein the processors are programmed to process data from the sensors and transmit processed data to vehicles.

22. The apparatus of claim 11 wherein the solar power source is supported above the half-shells thereby protecting the sensors and processors from weather.

23. An autonomous vehicle infrastructure apparatus comprising two half-shells, each half-shell comprising:
an inner wall;
an outer wall;
a plurality of sensors mounted on the outer wall; and
a processor; wherein
the two half-shells are configured to mount to one another surrounding a mounting pole such that the plurality of sensors have a panoramic field-of-view unencumbered by the mounting pole; and
the processors are programmed to process data from the sensors and transmit processed data to vehicles.

24. The apparatus of claim 23 wherein the outer wall is faceted and one sensor of the plurality of sensors is mounted to each facet.

25. The apparatus of claim 24 wherein the outer wall of each half-shell has three facets.

26. The apparatus of claim 23 further comprising a power pack having a solar collector and a battery.

27. The apparatus of claim 26 wherein the solar collector is mounted above the half-shells and the battery to protect the sensors and the battery from rain.
